(19) United States
(12) Patent Application Publication
(10) Pub. No.: US 2025/0113675 A1
(43) Pub. Date: Apr. 3, 2025

(54) LIGHT EMITTING DEVICE AND METHOD FOR MANUFACTURING LIGHT EMITTING DEVICE

(71) Applicant: NICHIA CORPORATION, Anan-shi (JP)

(72) Inventors: Yuta OKA, Awa-shi (JP); Shintaro NOMA, Anan-shi (JP)

(73) Assignee: NICHIA CORPORATION, Anan-shi (JP)

(21) Appl. No.: 18/829,692

(22) Filed: Sep. 10, 2024

(30) Foreign Application Priority Data
Sep. 28, 2023 (JP) 2023-168551
Jun. 27, 2024 (JP) 2024-103938

(51) Int. Cl. H01L 33/50

(52) U.S. Cl. CPC H10H 20/8514; H10H 20/0361

(57) ABSTRACT

A light emitting device includes: an inner light emitting part including an inner light emitting element, and an inner wavelength conversion member disposed on the inner light emitting element, and a plurality of outer light emitting parts disposed around the inner light emitting part and connected in parallel to one another, each outer light emitting part including an outer light emitting element, and an outer wavelength conversion member disposed on the outer light emitting element. The outer light emitting parts include a first light emitting part that includes a first light emitting element and a first wavelength conversion member, and a second light emitting part that includes a second light emitting element and a second wavelength conversion member.

### CROSS-REFERENCE TO RELATED APPLICATIONS

The present application claims priority under 35 U.S.C. § 119 to Japanese Patent Application No. 2023-168551, filed Sep. 28, 2023 and Japanese Patent Application No. 2024-103938 filed on Jun. 27, 2024, the contents of which is hereby incorporated by reference in its entirety.

### BACKGROUND

### 1. Technical Field

The present disclosure relates to a light emitting device and method for manufacturing the light emitting device.

### 2. Description of Related Art

For example, Japanese Patent Publication No. 2020-107728 discloses a light emitting device in which a cover member is disposed between light emitting elements arranged on a substrate and between the light transmissive members disposed on the light emitting elements.

### SUMMARY

In the case of connecting multiple light emitting elements in parallel, some of the light emitting elements can be damaged by heat.

The embodiments of the present disclosure made in view of the problem described above aim to provide a high reliability light emitting device.

As one aspect of the present disclosure, a light emitting device comprises an inner light emitting part that includes an inner light emitting element and an inner wavelength conversion member disposed on the inner light emitting element and a plurality of outer light emitting parts disposed around the inner light emitting part and connected in parallel to one another, each outer light emitting part including an outer light emitting element and an outer wavelength conversion member disposed on the outer light emitting element. The outer light emitting parts include a first light emitting part that includes a first light emitting element and a first wavelength conversion member, and a second light emitting part that includes a second light emitting element and a second wavelength conversion member. The area of the first wavelength conversion member is smaller than the area of the second wavelength conversion member in a plan view. The ratio of the forward voltage of the first light emitting element to the forward voltage of the second light emitting element is 0.95 to 1.05.

As one aspect of the present disclosure, a method for manufacturing a light emitting device comprises preparing a light transmissive sheet having a first main surface and a second main surface on a side opposite the first main surface, providing a plurality of protrusions including a first protrusion and a second protrusion on the light transmissive sheet in a plan view by providing a plurality of grooves on the first main surface, disposing a plurality of light emitting elements on the plurality of protrusions, including a step of disposing the light emitting element on an upper surface of each of the first protrusion and the second protrusion with a light emitting surface of the light emitting element facing the upper surface, disposing a light shielding member on the first main surface of the light transmissive sheet such that the light shielding member is disposed in the plurality of grooves and collectively holds the plurality light-emitting elements, removing a part of the light transmissive sheet from the second main surface side to expose the light shielding member disposed in the grooves, and obtaining, by individualizing, a light emitting device comprising an inner light emitting part that includes an inner light emitting element and an inner wavelength conversion member disposed on the inner light emitting element and a plurality of outer light emitting parts disposed around the inner light emitting part, each outer light emitting part including an outer light emitting element and an outer wavelength conversion member disposed on the outer light emitting element. The step of disposing the plurality of light emitting elements comprises a step of disposing the light emitting element on the second protrusion such that an outer periphery of the light emitting element disposed on the second protrusion is located inside an outer periphery of the second protrusion in a plan view, and a step of disposing the light emitting element on the first protrusion such that a part of the outer periphery of the light emitting element disposed on the first protrusion is located outside an outer periphery of the first protrusion in a plan view. The step of disposing the light shielding member comprises a step of not covering the upper surface of the light-emitting element disposed on the second protrusion with the light shielding member and covering a part of the upper surface of the light-emitting element disposed on the first protrusion with the light shielding member.

According to the embodiments of the present disclosure, a high reliability light emitting device that includes a number of light emitting elements connected in parallel can be provided.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1 is a schematic plan view of a light emitting device according to a first embodiment.

FIG. 2 is a schematic cross-sectional view taken along line II-II in FIG. 1.

FIG. 3 is an enlarged view of the region D in FIG. 1.

FIG. 4 is a circuit diagram explaining how light emitting elements 10 are connected.

FIG. 5 is a schematic plan view of a light emitting device according to a second embodiment.

FIG. 6 is a schematic cross-sectional view taken along line VI-VI in FIG. 5.

FIG. 7 is a schematic cross-sectional view explaining a process in a method of manufacturing the light emitting device according to the first embodiment.

FIG. 8 is a schematic cross-sectional view explaining a process in the method of manufacturing a light emitting device according to the first embodiment.

FIG. 9 is a schematic cross-sectional view explaining a process in the method of manufacturing a light emitting device according to the first embodiment.

FIG. 10 is a schematic cross-sectional view explaining a process in the method of manufacturing a light emitting device according to the first embodiment.

FIG. 11 is a schematic cross-sectional view explaining a process in the method of manufacturing a light emitting device according to the first embodiment.

FIG. 12A is a schematic plan view of a light emitting device according to a third embodiment.

FIG. 12B is a schematic cross-sectional view taken along line XII-XII in FIG. 12A.

FIG. 13 is a schematic cross-sectional view explaining a process in the method of manufacturing a light emitting device according to the third embodiment.

FIG. 14 is a schematic cross-sectional view explaining a process in the method of manufacturing a light emitting device according to the third embodiment.

FIG. 15 is a schematic cross-sectional view explaining a process in the method of manufacturing a light emitting device according to the third embodiment.

### DETAILED DESCRIPTION

### Embodiments

Light emitting devices and methods of manufacturing a light emitting device according to certain embodiments of the present disclosure will be explained below with reference to the accompanying drawings. The illustrations of light emitting devices and methods of manufacturing the same are provided for the purpose of giving shape to the technical ideas of the embodiments of the present disclosure without limiting the invention thereto. The dimensions, materials, shapes, relative positions of the elements in the embodiments described below are not intended to limit them to those described unless otherwise specifically noted, and are merely provided for explanation purposes. The sizes of and positional relationships between members shown in each drawing might be exaggerated for clarity of explanation. Moreover, in the description below, the same designations or reference numerals basically show the same members or those of similar quality, for which detailed explanation will be omitted as appropriate. An end face that shows a cut section might be used as a cross-sectional view.

In the description below, terms indicating specific directions or positions (e.g., “upper,” “on,” “lower,” “under,” and other terms including or related to these) may be used. These terms, however, are merely used to make the relative directions or positions in the drawings being referenced more easily understood. As long as the relationship between relative directions or positions indicated with the terms such as “upper,” “on,” “lower,” “under,” or the like is the same as those in a referenced drawing, the layout of the elements in other drawings or actual products outside of the present disclosure does not have to be the same as those shown in the referenced drawing. The positional relationship expressed with the term “on (or under)” in the present specification includes the case in which a member is in contact with another member, and the case in which a member is not in contact with, but positioned above (or under) another member.

Unless otherwise specifically noted, a member covering an object includes not only the case in which a member directly covers an object in contact with the object, but also the case in which a member indirectly covers an object without contacting the object. In the present specification, moreover, the term “area” means an area of an object in a plan view unless specifically noted otherwise.

### 1. First Embodiment

### 1.1. Overall Structure

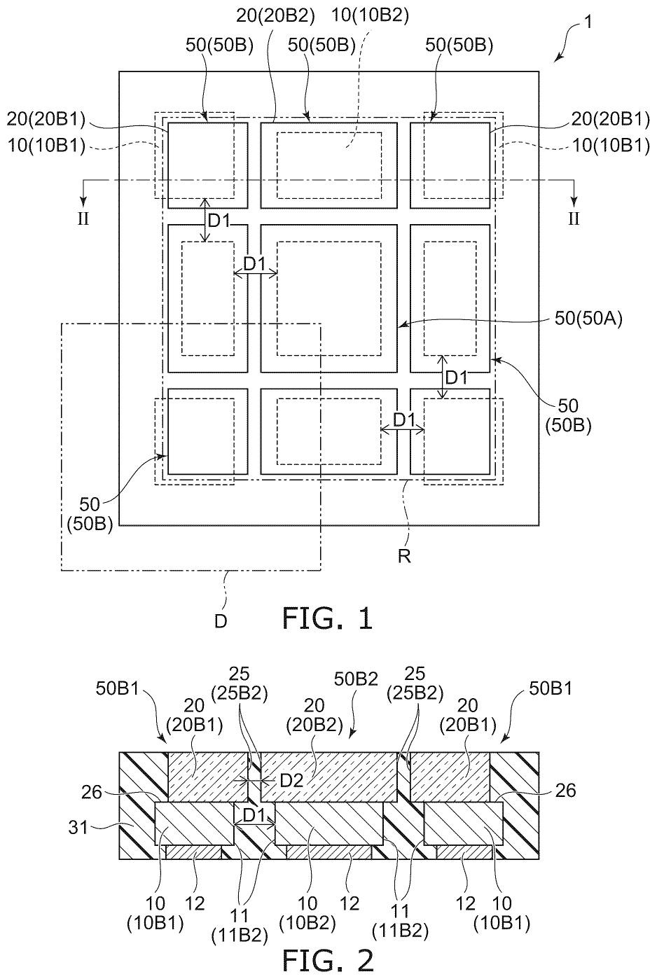

A light emitting device 1 according to a first embodiment will be explained with reference to FIG. 1 to FIG. 4. The light emitting device 1 includes multiple light emitting parts 50. The light emitting parts 50 include an inner light emitting part 50A that is placed in the center in a plan view, and outer light emitting parts 50B that are placed around the inner light emitting part 50A and connected parallel to one another. In the example shown in FIG. 1, the light emitting device 1 has nine light emitting parts 50. Specifically, one inner light emitting part 50A and eight outer light emitting parts 50B around the inner light emitting part 50A are arranged in a matrix in a quadrangular region (hereinafter also referred to as the quadrangular region R) in the plan view. In the present specification, a quadrangular shape includes both a square and a rectangle. The number and the layout of the light emitting parts 50 are not limited to those described above, and the light emitting device 1 may include, for example, a light emitting part in addition to the inner light emitting part 50A and the outer light emitting parts 50B. In the present disclosure, the inner light emitting part 50A, the outer light emitting parts 50B, and a light emitting part provided in addition to the inner light emitting part 50A and the outer light emitting parts 50B are sometimes simply referred to as light emitting parts 50 without being distinguished.

The light emitting device 1 can be used as a light source for a flashlight of an image pick-up device for capturing images (including still images and videos). The image pick-up device is installed, for example, in a mobile communication device. In the case of using the light emitting device 1 according to this embodiment as a light source in a flashlight, for example, the irradiation of light can be switched between a first irradiation mode in which only the inner light emitting part 50A in the center in a plan view is lit and a second irradiation mode in which both the inner light emitting part 50A and the outer light emitting parts 50B are lit. The first irradiation mode has a narrower irradiation angle than the second irradiation mode. Accordingly, the light emitting device 1 capable of switching the light emission between the first irradiation mode and the second irradiation mode allows an image pick-up device to capture an image in accordance with the type of shooting, such as a close-up or telescopic shot.

Each light emitting part 50 has a light emitting element 10 and a wavelength conversion member 20. In the present specification, for explanation purposes, the word “inner” is added before light emitting element and light transmissive member of the inner light emitting part 50A, and the letter “A” is added to the reference numerals for the light emitting element and the light transmissive member of the inner light emitting part 50A. The word “outer” is added before light emitting element and light transmissive member of each outer light emitting part 50B, and the letter “B” is added to the reference numerals for the light emitting element and the light transmissive member of each outer light emitting part 50B.

The inner light emitting part 50A has an inner light emitting element 10A. The outer light emitting parts 50B each have an outer light emitting element 10B. In some cases, the light emitting element 10 of each light emitting part 50 might be simply referred to as a light emitting element 10 without making distinctions among the inner light emitting element 10A, the outer light emitting elements 10B, and a light emitting element provided in addition to the inner light emitting element 10A and the outer light emitting elements 10B.

The outer light emitting parts 50B are connected in parallel and emit light as a group. This allows for the switching between the state in which all of the outer light emitting parts 50B are lit and the state in which all of them are unlit. Switching between the all-lit state and the all-unlit state of the outer light emitting parts 50 can be controlled by using, for example, an emission control unit. Collectively turning on or off the outer light emitting parts 50B requires only one channel in the emission control unit that is allotted to the outer light emitting parts 50B, thereby simplifying the wiring between the light emitting device 1 and the emission control unit.

In the case of connecting multiple light emitting parts 50 in parallel, the differences in area among the light emitting elements or the like can cause the forward voltages Vf of and the amount of current flowing across the light emitting parts 50 to differ. Specifically, connecting, in parallel, a light emitting part 50 having a light emitting element 10p of a small area and a light emitting part 50 having a light emitting element 10q of a large area can fluctuate the values of the electric current that flow across the light emitting elements 10 because of the current-voltage characteristics of the light emitting elements 10. Furthermore, the current density for a light emitting element 10p having a small area among the light emitting elements 10 tends to increase. Because the forward voltage Vf of a light emitting element 10 fluctuates depending on the current density, the forward voltage Vf of the light emitting element 10p having a small area becomes high, allowing more current to flow across a light emitting element 10q having a relatively low forward voltage Vf (i.e., a light emitting element having a large area) to thereby increase the amount of heat generated by the light emitting element 10q. As a result, heat damage can occur to the light emitting element 10q. Furthermore, when the amounts of electric current flowing across the light emitting parts 50 are different from one another, the brightness of the light exiting the light emitting parts 50 tends to be nonuniform. This might cause irradiation unevenness in the irradiation surface when all of the light emitting parts 50 are lit collectively.

In a conventional light emitting device in which a wavelength conversion member is provided for each light emitting element, the areas of the wavelength conversion members were sometimes selected in conformity with the areas of the light emitting elements to allow the light from the light emitting elements to transmit through the wavelength conversion members efficiently. In other words, a light emitting element having a large area was placed under a wavelength conversion member having a large area, and a light emitting element having a small area was placed under a wavelength conversion member having a small area. For this reason, in a conventional light emitting device that included wavelength conversion members having different areas, the areas of the light emitting elements provided thereunder also differed. When such light emitting elements were connected in parallel, the forward voltages Vf of and the amounts of electric current flowing across the light emitting parts 50 could vary as described above. In this embodiment, a light emitting device that can solve the problems associated with light emitting parts 50 connected in parallel described above is provided.

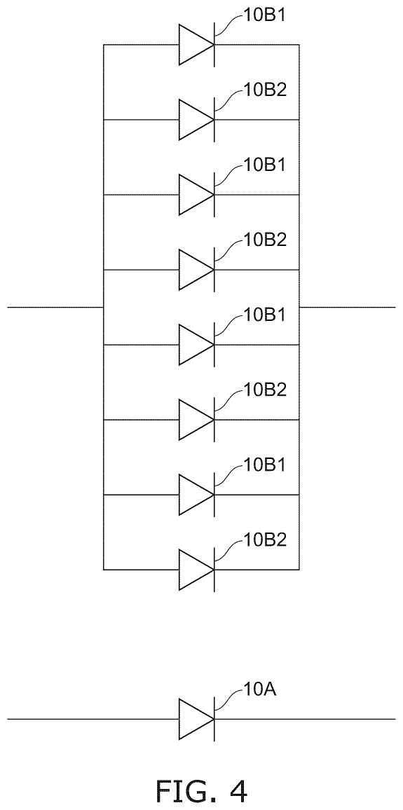

The outer light emitting parts 50B include a first light emitting part 50B1 and a second light emitting part 50B2. In the light emitting device 1 shown in FIG. 1, the first light emitting parts 50B1 are placed at the corners of the quadrangular region R and the second light emitting parts 50B2 are arranged between the first light emitting parts along the sides of the quadrangular region R in the plan view. Each of the first light emitting parts 50B1 has a first light emitting element 10B1 and a first wavelength conversion member 20B1. Each of the second light emitting parts 50B2 has a second light emitting element 10B2 and a second wavelength conversion member 20B2. As shown in FIG. 4, the first light emitting elements 10B1 of the first light emitting parts 50B1 and the second light emitting elements 10B2 of the second light emitting parts 50B2 are connected in parallel with one another. The inner light emitting element 10A of the inner light emitting part 50A is connected using an independent channel (current path) from that for the first light emitting elements 10B1 of the first light emitting parts 50B1 and the second light emitting elements 10B2 of the second light emitting parts 50B2. This allows for the switching between the first irradiation mode in which only the inner light emitting part 50A emits light and the second irradiation mode in which both the inner light emitting part 50A and the outer light emitting parts 50B emit light, as described above.

In this embodiment, the first wavelength conversion members 20B1 and the second wavelength conversion members 20B2 are quadrangular in the plan view. The area S1 of a first wavelength conversion member 20B1 in the plan view is smaller than the area S2 of a second wavelength conversion member 20B2. Specifically, the ratio of the area S1 of a first wavelength conversion member 20B1 to the area S2 of a second wavelength conversion member 20B2 is, for example, 0.8 or lower, or 0.6 or lower. Furthermore, the ratio of the area S1 of a first wavelength conversion member 20B1 to the area S2 of a second wavelength conversion member 20B2 is, for example, 0.2 or higher, or 0.5 or higher.

The ratio of the forward voltage Vf1 of a first light emitting element 10B1 to the forward voltage Vf2 of a second light emitting element 10B2 is, for example, 0.95 to 1.05. In the light emitting device 1 in this embodiment, the difference in area between a first light emitting element 10B1 and a second light emitting element 10B2 in a plan view is reduced to reduce the difference in forward voltage Vf between the first light emitting element 10B1 and the second light emitting element 10B2. In a plan view, the ratio of the area of a first light emitting element 10B1 to the area of a second light emitting element 10B2 is 0.7 to 1.3. Setting the area of a first light emitting element 10B1 in the range described above can reduce the difference in current density between the first light emitting element 10B1 and the second light emitting element 10B2 to thereby achieve the forward voltage Vf ratio of the first light emitting element 10B1 to the second light emitting element 10B2 of 0.95 to 1.05.

The light emitting elements 10 have element lateral faces 11. In the inner light emitting element 10A, the lateral faces that oppose the element lateral faces 11 of the outer light emitting elements 10B will be referred to as inner element lateral faces 11A. In the outer light emitting elements 10B, the lateral faces that oppose the element lateral faces 11 of the inner light emitting element 10A will be referred to as inner element opposing lateral faces 11B1. Furthermore, in the outer light emitting elements 10B, the lateral faces that oppose the element lateral faces 11 of other outer light emitting elements 10B will be referred to as outer element opposing lateral faces 11B2.

The wavelength conversion members 20 have member lateral faces 25. In the inner wavelength conversion member 20A, the lateral faces that oppose the member lateral faces 25 of the outer wavelength conversion members 20B will be referred to as the inner member lateral faces 25A. In the outer wavelength conversion members 20B, the lateral faces that oppose the member lateral faces 25 of the inner wavelength conversion member 20A will be referred to as inner member opposing lateral faces 25B1. In the outer wavelength conversion members 20B, moreover, the lateral faces that oppose the member lateral faces 25 of other outer wavelength conversion members 20B will be referred to as outer member opposing lateral faces 25B2.

The first light emitting elements 10B1 of the first light emitting parts 50B1 have outer element opposing lateral faces 11B2, and the first wavelength conversion members 20B1 of the first light emitting parts 50B1 have outer member opposing lateral faces 25B2. The second light emitting elements 10B2 of the second light emitting parts 50B2 each have an inner element opposing lateral face 11B1 and outer element opposing lateral faces 11B2, and the second wavelength conversion members 20B2 of the second light emitting parts 50B2 each have an inner member opposing lateral face 25B1 and outer member opposing lateral faces 25B2. The separation distance D1 between an outer element opposing lateral face 11B2 of a first light emitting element 10B1 and the outer element opposing lateral face 11B2 of an adjacent second light emitting element 10B2 is larger than the separation distance D2 between the outer member opposing lateral face 25B2 of the first wavelength conversion member 20B1 and the outer member opposing lateral face 25B2 of the second wavelength conversion member 20B2. Such a structure allows the light emitted by the light emitting elements 10 to be guided to the wavelength conversion members 20 in a definitive manner.

In the light emitting device 1, the inner light emitting element 10A and the outer light emitting elements 10B are arranged at equal intervals, i.e., have the same separation distance, in a plan view. In other words, as shown in FIG. 1, the first light emitting elements 10B1 and the second light emitting elements 10B2, as well as the inner light emitting element 10A and the second light emitting elements 10B2 are arranged at equal intervals interposing the separation distance D1. Arranging the first light emitting elements 10B1, second light emitting elements 10B2, and the inner light emitting element 10A using the same separation distance D1 can simplify the manufacturing of a light emitting device 1 and improve the positioning accuracy of the light emitting elements. The separation distance D1 is 3 μm to 200 μm, preferably 3 μm to 120 μm. This can miniaturize the light emitting device 1.

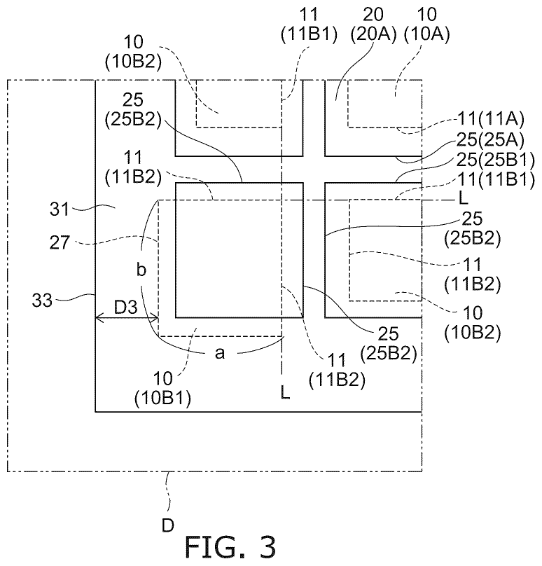

The outer light emitting elements 10B are arranged such that on a line L, which is an extension of the inner lateral face of a light emitting element 10 of an outer light emitting part 50B, the inner lateral face of the light emitting element 10 of an adjacent outer light emitting part 50B is positioned in a plan view. Specifically, as shown in FIG. 3, the outer light emitting elements 10B are arranged such that on the line L, which is an extension of the outer element opposing lateral face 11B2 of a first light emitting element 10B1, the inner element opposing lateral face 11B1 of an adjacent second light emitting element 10B2 is positioned.

In the plan view, the separation distance D3 between an outer lateral face 33 of the light shielding member 31 and an outer lateral face 27 of a first light emitting element 10B1 is preferably 0.3 times the length of a short side of the first light emitting element 10B1 or larger, and may be set to 0.5 times or larger as an example. This can reduce the external leakage of light from the first light emitting element 10B1. The separation distance D3 is, for example, five times the distance a of a short side of the first light emitting element 10B1 or smaller, or three times or smaller. In the case in which the shape of a first light emitting element 10B1 is a square in a plan view, a short side of a light emitting element corresponds to any side of the square shaped first light emitting element 10B1.

### 1.2. Light Emitting Element 10

A light emitting element 10 has a semiconductor structure. The light emitting element 10 may further include a growth substrate, such as a silicon or sapphire substrate. The semiconductor structure includes a nitride semiconductor. In the present specification, nitride semiconductors include semiconductors of all compositions obtained by varying the composition ratio x and y within their ranges in the chemical formula InₓAlyGa_{1-x-y}N (0≤x≤1, 0≤y≤1, x+y≤1). Moreover, nitride semiconductors include those further containing a group V element in addition to nitrogen (N), and those further containing various elements added for controlling various physical properties such as conductivity type. The semiconductor structure includes a p-type layer, an n-type layer, and an active layer. The active layer is an emission layer that emits light, and has, for example, a MQW (multiple quantum well) structure including multiple barrier layers and multiple well layers. The light emitted by the active layer is, for example, visible or ultraviolet light. For example, multiple light emitting elements 10 having the optical characteristics (brightness, chromaticity, etc.) that fall within predetermined ranges are selected for use in a light emitting device 1.

Each light emitting element 10 further includes element electrodes 12. The element electrodes 12 are disposed, for example, on the lower face of the semiconductor structure and electrically connected to the semiconductor structure. Each light emitting element 10 has at least two element electrodes 12. One of the two element electrodes 12 functions as an anode electrode and the other functions as a cathode electrode.

### 1.3. Wavelength Conversion Member 20

The inner light emitting part 50A has an inner wavelength conversion member 20A disposed on the inner light emitting element 10A. The outer light emitting parts 50B each have an outer wavelength conversion member 20B disposed on the outer light emitting element 10B. On occasion, the wavelength conversion member of each light emitting part 50 might be simply referred to as a wavelength conversion member 20 without making distinctions among the inner wavelength conversion member 20A, the outer wavelength conversion members 20B, and a wavelength conversion member provided in addition to the inner wavelength conversion member 20A and the outer wavelength conversion members 20B.

Wavelength conversion members 20 can convert the wavelength of and diffuse the light emitted by the light emitting elements 10. Specific materials for the wavelength conversion members 20 will be discussed in detail later.

Each wavelength conversion member 20 may have a phosphor layer disposed on the light emitting element 10, and a light diffusing layer disposed on the phosphor layer. As one example, the inner wavelength conversion member 20A may have an inner phosphor layer disposed on the inner light emitting element 10A, and an inner light diffusing layer disposed on the inner phosphor layer. Each outer wavelength conversion member 20B may have an outer phosphor layer disposed on the outer light emitting element 10B, and an outer light diffusing layer disposed on the outer phosphor layer. The wavelength conversion members 20 may only have a phosphor layer, or include a layer in addition to the phosphor layer and the light diffusing layer. The layer provided in addition to the phosphor layer and the light diffusing layer is, for example, the light transmitting layer not containing any phosphor or light diffusing material described later.

A phosphor layer contains a phosphor that converts the wavelength of at least a portion of the light emitted by a light emitting element 10. For the phosphor layer, one made of a resin, ceramic, glass, or the like that contains a phosphor, a sintered body of a phosphor, or the like can be used. The phosphor layer may be a formed body of a resin, ceramic, or glass with a resin layer containing a phosphor disposed on one of the faces of the formed body.

For the resin for the phosphor layer, for example, a thermosetting resin, such as a silicone resin, silicone modified resin, epoxy resin, epoxy modified resin, or phenol resin can be used. For the resin for the phosphor layer, a silicone resin or its modified resin that is highly light resistant and heat resistant is particularly suited.

For the phosphor, for example, yttrium aluminum garnet based phosphors (e.g., Y₃(Al,Ga)₅O₁₂:Ce), lutetium aluminum garnet based phosphors (e.g., Lu₃(Al,Ga)₅O₁₂:Ce), terbium aluminum garnet based phosphors (e.g., Tb₃(Al,Ga)₅O₁₂:Ce), CCA-based phosphors (e.g., Ca₁₀(PO₄)₆Cl₂:Eu), SAE based phosphors (e.g., Sr₄Al₁₄O₂₅:Eu), chlorosilicate based phosphors (e.g., Ca₈MgSi₄O₁₆Cl₂:Eu), silicate based phosphors (e.g., (Ba, Sr,Ca,Mg)₂SiO₄:Eu), oxynitride based phosphors, such as β-SiAlON phosphors (e.g., (Si,Al)₃(O,N)₄Eu) or α-SiAlON phosphors (e.g., Ca(Si,Al)₁₂(O,N)₁₆:Eu), nitride based phosphors, such as LSN phosphors (e.g., (La,Y)₃Si₆N₁₁:Ce), BSESN-based phosphors (e.g., (Ba,Sr)₂Si₅N₈:Eu, SLA based phosphors (e.g., SrLiAl₃N₄:Eu), CASN-based phosphors (e.g., CaAlSiN₃:Eu), or SCASN-based phosphors (e.g., (Sr,Ca)AlSiN₃:Eu), fluoride based phosphors, such as KSF-based phosphors (e.g., K₂SiF₆:Mn), KSAF-based phosphors (e.g., K₂(Si₁₋ₓ,Alₓ)F₆₋ₓ: Mn where x satisfies 0<x<1), or MGF-based phosphors (e.g., 3.5MgO·0.5MgF₂·GeO₂:Mn), quantum dots having a Perovskite structure (e.g., (Cs,FA,MA)(Pb,Sn)(F,Cl,Br,I)₃ where FA and MA represent formamidinium and methylammonium, respectively), group II-VI quantum dots (e.g., CdSe), group III-V quantum dots (e.g., InP), or quantum dots having a chalcopyrite structure (e.g., (AgCu)(In,Ga)(S,Se)₂) can be used.

The phosphor layer may contain a single or multiple types of phosphors. For example, the light emitting parts 50 output mixed color light resulting from mixing the color of visible light emitted by the light emitting elements 10 and the color of light emitted by the phosphor in the phosphor layer when excited by the light from the light emitting elements 10. As another example, the light emitting parts 50 output mixed color light resulting from mixing the color of ultraviolet light emitted by the light emitting elements 10 and the color of light emitted by the phosphor in the phosphor layer when excited by the light from the light emitting elements 10. The light emitting parts 50 may be composed of those emitting light of the same peak emission wavelength, or those emitting light of different peak emission wavelengths from one another.

The upper face of a light diffusing layer can constitute the upper face of the wavelength conversion member 20. The light diffusing layer can contain a light diffusing material that diffuses the light from the light emitting element 10. For the light diffusing layer, one made of a resin, ceramic, glass, or the like that contains a light diffusing material can be used. Examples of light diffusing materials include titanium oxide, silicon oxide, and the like. For the resin for the light diffusing layer, a similar resin to that for the phosphor layer can be used.

The wavelength conversion members 20 can further include a light transmitting layer disposed between the light emitting element 10 and the phosphor layer. As one example, the inner wavelength conversion member 20A may further include an inner light transmitting layer disposed between the inner light emitting element 10A and the inner phosphor layer. Each of the outer wavelength conversion members 20B can further have an outer light transmitting layer disposed between the outer light emitting element 10B and the outer phosphor layer.

As one example, the thickness of the light diffusing layer in the up and down direction (hereinafter simply referred to as “thickness” on occasion) is 10 μm to 150 μm, or 20 μm to 80 μm. The thickness of the phosphor layer is, for example, 20 μm to 150 μm, or 30 μm to 100 μm. The thickness of the light transmitting layer 23 is, for example, 1 μm to 150 μm, or 10 μm to 60 μm. The wavelength conversion member 20 may comprise only one or only two of the light diffusing layer, the phosphor layer, and the light transmitting layer.

### 1.4. Light Shielding Member 31

The light emitting device 1 further comprises a light shielding member 31. In the case in which the light shielding member 31 includes the light reflecting additive described later, the reflectance of the light shielding member 31 for the peak wavelength of the light from the light emitting elements 10 is, for example, 70% or higher, preferably 80% or higher. In the case in which the light shielding member 31 contains a light absorbing additive, the absorption of the light shielding member 31 for the peak wavelength of the light from the light emitting elements 10 is, for example, 50% or higher, preferably 70% or higher. The reflectance and the absorption can be measured by using a spectral photometer, for example. The light shielding member 31 has insulation properties.

The light shielding member 31 integrally holds the inner light emitting part 50A and the outer light emitting parts 50B, and fills around the light emitting parts 50. The upper faces of the wavelength conversion members 20 are exposed from the light shielding member 31. The upper faces of the wavelength conversion members 20 make up the emission face of the light emitting device 1.

The light emitting device 1 equipped with a light shielding member 31, in the case in which one light emitting part 50 is lit and an adjacent light emitting part 50 is unlit, can reduce the leakage of the outgoing light from the lit light emitting part 50 to the wavelength conversion member 20 of the adjacent light emitting part 50 to cause the wavelength conversion substance contained in the wavelength conversion member 20 to emit light, for example. This, as a result, can increase the contrast of the light irradiated by the light emitting device 1.

As shown in FIG. 2, the first light emitting parts 50B1 are such that the upper faces 26 of the first light emitting elements 10B1 are partly covered by the light shielding member 31. Specifically, the upper face 26 of a first light emitting part 50B1 is partly covered by the light shielding member 31 on the side that is not adjacent to another outer light emitting part 50B. As one example, as shown in FIG. 1 and FIG. 2, the upper face 26 of each first light emitting part 50B1 is partly covered by the light shielding member 31 on the outer side that is not adjacent to a second light emitting part 50B2 in the plan view. On the other hand, the upper faces 26 of the second light emitting elements 10B2 in the second light emitting parts 50B2 are not covered by the light shielding member 31.

The light shielding member 31 may contain an additive. The thermal conductivity of the additive is, for example, 0.05 W/m·K to 2000 W/m·K, preferably 0.1 W/m·K to 400 W/m·K, more preferably 1 W/m·K to 250 W/m·K.

The light shielding member 31 preferably has light reflecting properties and reflects the light emitted by the light emitting parts 50 or light absorbing properties to absorb the light emitted by the light emitting parts 50. In the case in which the light shielding member 31 has light reflecting properties, the light from each light emitting part 50 can be reflected by the light shielding member 31 efficiently to thereby increase the luminous flux of the light emitting device 1.

For example, a resin member containing a light reflecting additive or a light absorbing additive can be used as the light shielding member 31. Examples of light reflecting additives include titanium oxide, zinc oxide, magnesium oxide, magnesium carbonate, magnesium hydroxide, calcium carbonate, calcium hydroxide, calcium silicate, magnesium silicate, barium titanate, barium sulfate, aluminum hydroxide, aluminum oxide, zirconium oxide, silicon oxide, and the like. One of these can be used singly, or two or more in combination. For the light absorbing additive, carbon black or the like can be used. The resin member used as the light shielding member 31 can have a base material using a thermosetting resin, such as an epoxy resin, silicone resin, silicone modified resin, or phenol resin as a main component.

The reflectance of the light reflecting additive contained in the light shielding member 31 can be 80% to 99%, for example, 90% to 99%. The amount of an additive contained in the light shielding member 31 is, for example, 30 mass % to 80 mass %, preferably 55 mass % to 80 mass % when the total mass of the light shielding member 31 is 100%.

The light emitting parts 50 can further include external electrodes. The external electrodes are disposed on the lower faces of the element electrodes 12 of the light emitting elements 10, and electrically connected to the light emitting elements 10. In the case in which the light emitting parts 50 include external electrodes, each light emitting part 50 has at least two external electrodes. One of the two external electrodes functions as an anode electrode, and the other as a cathode electrode. Each external electrode is, for example, a metal layer formed by sputtering or the like. The lower faces of the external electrodes are exposed from the light shielding member 31 and bonded via solder or the like to the conducting parts arranged on the substrate on which the light emitting device 1 will be mounted.

### 1.5. Summary

As described above, the light emitting device 1 according to this embodiment includes an inner light emitting part 50A and multiple outer light emitting parts 50B that are disposed around the inner light emitting part 50A and connected in parallel to one another. The inner light emitting part 50A has an inner light emitting element 10A and an inner wavelength conversion member 20A disposed on the inner light emitting element 10A. The outer light emitting parts 50B each include an outer light emitting element 10B and an outer wavelength conversion member 20B disposed on the outer light emitting part 10B. The outer light emitting parts 50B include a first light emitting part 50B1 that includes a first light emitting element 10B1 and a first wavelength conversion member 20B1 and a second light emitting part 50B2 that includes a second light emitting element 10B2 and a second wavelength conversion member 20B2. The area of a first wavelength conversion member 20B1 is smaller than the area of a second wavelength conversion member 20B2 in a plan view, and the ratio of the forward voltage Vf1 of a first light emitting element 10B1 to the forward voltage Vf2 of a second light emitting element 10B2 is 0.95 to 1.05. Such a structure can reduce the heat damage that can occur in a light emitting device 1 that includes light emitting elements 10 connected in parallel, thereby providing a high reliability light emitting device.

Connecting, in parallel, light emitting parts 50 having light emitting elements 10p of a small area and light emitting parts 50 having light emitting elements 10q of a large area can change the values of the current flowing across the light emitting elements 10 depending on the current-voltage characteristics of the light emitting elements 10. Moreover, a light emitting element 10p of a small area among the light emitting elements 10 tends to have a high current density. Because the forward voltage Vf of a light emitting element 10 fluctuates depending on the current density, the forward voltage Vf of a light emitting element 10p having a small area becomes high to allow more current to flow across a light emitting element 10q having a relatively low forward voltage Vf (i.e., having a large area), which increases the amount of heat generated by the light emitting element 10q. This can cause heat damage to the light emitting element 10q. In contrast, the light emitting device 1 of this embodiment, which has the structure described above, can reduce the occurrence of heat damage.

Furthermore, in the light emitting device 1 according to this embodiment, the difference between the area of a first light emitting element 10B1 of a first light emitting part 50B disposed at a corner of the quadrangular region R and the area of a second light emitting element 10B2 of a second light emitting part 50B2 disposed along a side of the quadrangular region R is reduced. Specifically, the ratio of the area A1 of a first light emitting element 10B1 to the area A2 of a second light emitting element 10B2 is set as 0.7 to 1.3. Reducing the difference between the area A1 of a first light emitting element 10B1 and the area A2 of a second light emitting element 10B2 as described above can reduce the fluctuation of the forward voltage Vf of each outer light emitting element 10B.

In this embodiment, moreover, the light emitting device 1 further comprises a light shielding member 31 that integrally holds the inner light emitting part 50A and the outer light emitting parts 50B while partly covering the upper faces 26 of the first light emitting elements 10B1. Such a structure makes it easy to reduce the differences among the plan view areas of the outer light emitting elements 10B of the outer light emitting parts 50B without being affected by the differences in the plan view areas among the outer wavelength conversion members 20B of the outer light emitting parts 50B.

### 2. Second Embodiment

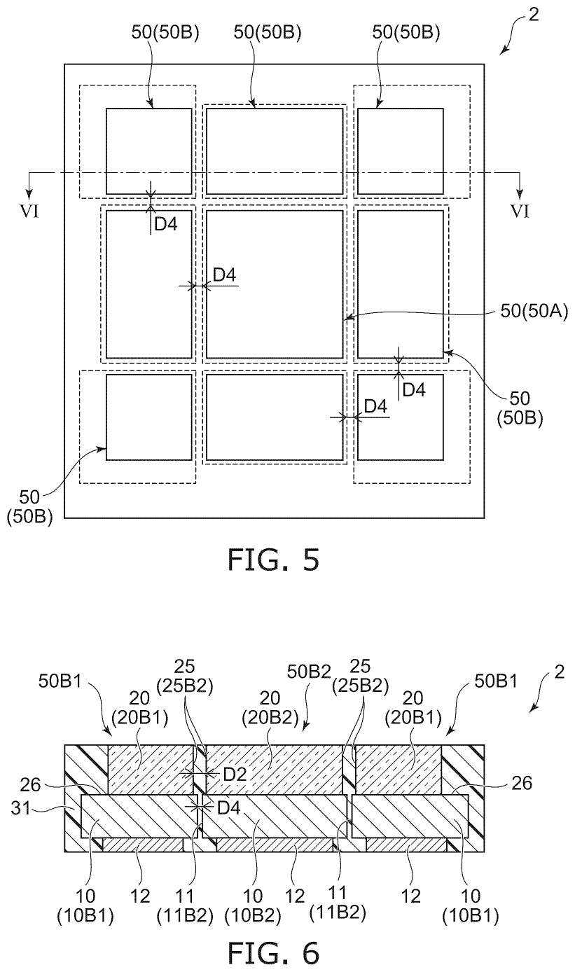

A light emitting device 2 according to a second embodiment will be explained next with reference to FIG. 5 and FIG. 6. In the embodiments described below, the features that differ from those of the first embodiment will be focused. Elements that are the same as those of the first embodiment will be denoted with the same reference numerals.

The light emitting device 2 according to the second embodiment differs from the first embodiment such that the light shielding member 31 covers a portion of the upper face of the light emitting element 10 in each of the inner light emitting part 50A and the outer light emitting parts 50B. In other words, in the light emitting device 2, as shown in FIG. 5, the light shielding member 31 covers a portion of each of the light emitting elements 10 of the inner light emitting part 50A placed in the center of the quadrangular region R, the first light emitting parts 50B1 placed at the corners of the quadrangular region R, and the second light emitting parts 50B2 placed along the sides of the quadrangular region R.

Specifically, in the light emitting device 2, in a plan view, the areas of the light emitting elements 10 of the inner light emitting part 50A and the outer light emitting parts 50B are larger than the areas of their respective wavelength conversion members 20. As one example, as shown in FIG. 5, in each of the light emitting parts 50, the light emitting element 10 and the wavelength conversion member 20 are disposed such that the outline of the wavelength conversion member 20 is located inward of the outline of the light emitting element 10 in the plan view, and the upper faces 26 of the light emitting elements 10 are covered by the light shielding member 31 along the outer perimeters of the light emitting elements 10. As shown in FIG. 6, the separation distance D2 between the member lateral faces 25 of two adjacent wavelength conversion members 20 is larger than the separation distance D4 between the element lateral faces 11 of the light emitting elements 10. Such a structure can reduce the separation distance between the light emitting elements 10, allowing for the employment of larger light emitting elements assuming that the plan area of the light emitting device 2 and the number of light emitting elements are the same. This can increase the light extraction of the light emitting device 2.

### 3. Third Embodiment

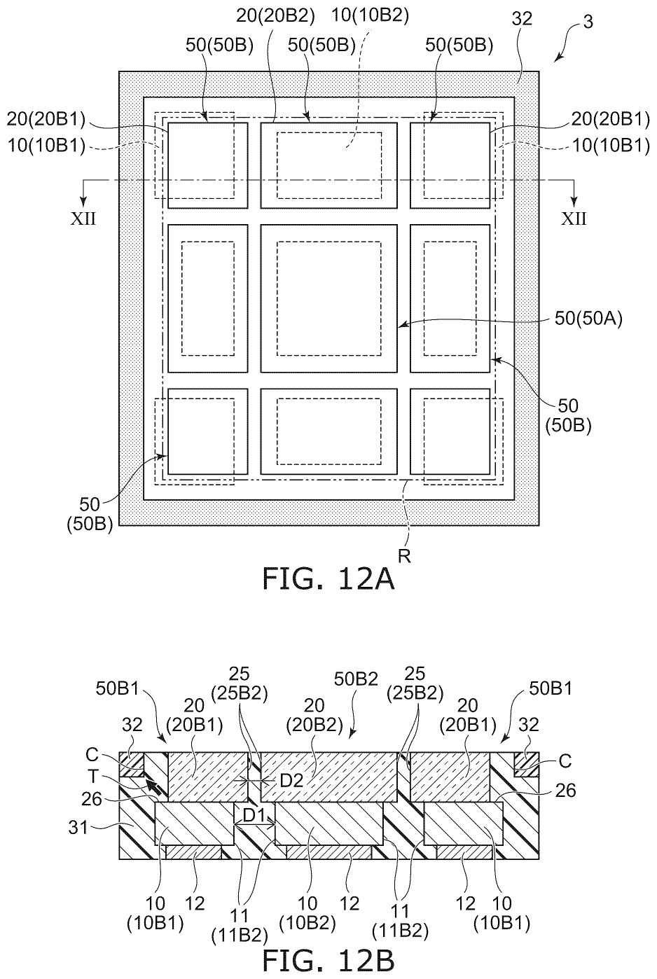

A light emitting device 3 according to a third embodiment will be explained next with reference to FIG. 12A and FIG. 12B. In the embodiments described below, the features that differ from those of the first embodiment will be focused. Elements that are the same as those of the first embodiment will be denoted with the same reference numerals.

The light emitting device 3 according to the third embodiment differs from the first embodiment such that light emitting device 3 further includes a light absorbing part 32 on the outer upper surface of the light shielding member 31. That is, as shown in FIG. 12A, the light emitting device 3 further includes a light absorbing part 32 that surrounds a plurality of outer wavelength conversion members 20B on the outer upper surface of the light shielding member 31, and that has a higher light absorption rate than the light shielding member 31. The light absorbing part 32 is disposed to surround the outside of the quadrangular region R. By including the light absorbing part 32, the light emitting device 3 can reduce stray light on an irradiation surface by absorbing part of light emitted from the plurality of light emitting elements 10, especially light emitted from the plurality of outer light emitting elements 10B, that is emitted toward an outer lateral face side of the light emitting device 3. Specifically, as shown in FIG. 12B, a part of an upper surface of the outer light emitting element 10B is embedded in the light shielding member 31. When the outer light emitting element 10B emits light, the main light of the outer light emitting element 10B is emitted to the outside through the outer wavelength conversion member 20B, while part of the light is emitted toward the outer lateral face direction of the light emitting device through the light shielding member 31. By including the light absorbing part 32 on the outer upper surface of the light shielding member 31, the light (e.g., arrow T in FIG. 12B) emitted to the outside through the light shielding member 31 can be absorbed by the light absorbing part 32, resulting in a light emitting device with reduced stray light on the irradiation surface.

The light absorbing part 32 has a higher light absorption rate than that of the light shielding member 31. For example, a light absorption rate of the light absorbing part 32 for light with a peak emission wavelength of 450 nm is 50% or more, 60% or more, and 70% or more. A light reflection rate of the light absorbing part 32 for light with a peak emission wavelength of 450 nm is 50% or less, 40% or less, and 30% or less. On the other hand, a light absorption rate of the light shielding member 31 for light with a peak emission wavelength of 450 nm is 30% or less, 20% or less, and 10% or less. A light reflection rate of the light shielding member 31 for light with a peak emission wavelength of 450 nm is 70% or more, 80% or more, and 90% or more. The light absorption rate and the light reflection rate can be measured using, for example, a spectrophotometer.

The light absorbing part 32 may be a member containing a light absorbing substance such as carbon black in a resin material, a member containing graphite, or a black part formed by irradiating the surface of the light shielding member 31 with laser light to alter titanium oxide or the like contained in the light shielding member 31. The altered titanium oxide has a smaller bandgap energy compared to titanium oxide before executing laser irradiation. The altered titanium oxide contained in the light absorbing part 32 has a smaller bandgap energy compared to titanium oxide contained in the other parts of the light shielding member 31. The titanium oxide contained in the light shielding member 31 is, for example, rutile-type titanium oxide.

In the light emitting device 3 according to the third embodiment, a recess C that surrounds a plurality of outer wavelength conversion members 20B is provided on the outer upper surface of the light shielding member 31, and the light absorbing part 32 is a resin member containing a light absorbing substance disposed in the recess C. By providing the recess C and disposing the light absorbing part 32 in the recess C, an increase in a size of the light emitting device 3 in a height direction can be reduced. The recess C may not be provided in the light emitting device 3, for example, a resin material containing a light absorbing substance may be applied on a planar surface of the outer upper surface of the light shielding member 31.

In the light emitting device 3 according to the third embodiment, an outer lateral face of the light absorbing part 32 is positioned on substantially the same plane as the outer lateral face of the light shielding member 31. This allows light emitted toward the outer lateral face direction of the light emitting device through the light shielding member 31 to be efficiently absorbed when the outer light emitting element 10B emits light, resulting in a light emitting device with reduced stray light on the irradiation surface. The light absorbing part 32 may be positioned inside the outer surface of the light shielding member 31 in a plan view.

### 4. Method of Manufacturing Light Emitting Device 1

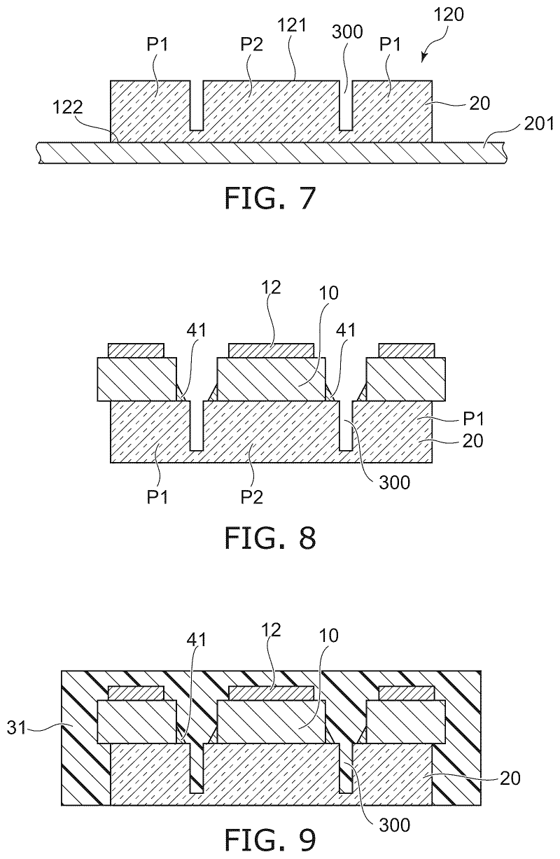

A method of manufacturing a light emitting device 1 according to the first embodiment will be explained below with reference to FIG. 7 to FIG. 11. In the method of manufacturing a light emitting device 1, as shown in FIG. 7, a process of forming grooves 300 on the first principal face 121 of a light transmissive sheet 120 is performed. A first support member 201 supports the light transmissive sheet 120 in contact with the second principal face 122 that opposes the first principal face 121. The light transmissive sheet 120 has, successively from the first principal face 121 side, a light transmitting layer, a phosphor layer, and a light diffusing layer.

In the process of forming grooves 300, a plurality of grooves 300 are formed in the first principal face 121 in a matrix in a plan view, for example. The grooves 300 can be formed by using, for example, a blade or a laser beam. The grooves 300 do not go through the light transmissive sheet 120, and the bottoms of the grooves 300 are positioned, for example, in the light diffusing layer. Alternatively, a light transmissive sheet 120 with preformed grooves 300 may be obtained by transfer such as purchasing in place of performing the process of forming grooves 300 in the light transmissive sheet 120.

By forming a plurality of grooves 300, the light transmissive sheet 120 includes a plurality of protrusions on the first principal face 121, including a first protrusion P1 and a second protrusion P2. As an example, the first protrusion P1 is a portion where the first light emitting element 10B1 will be disposed and will become the first wavelength conversion member 20B1. Also, as an example, the second protrusion P2 is a portion where the second light emitting element 10B2 will be disposed and will become the second wavelength conversion member 20B2. In FIG. 7, the second protrusion P2 is positioned inside, and the two first protrusions P1 are positioned outside sandwiching the second protrusion P2. FIG. 7 may illustrate a cross-sectional view through a portion that will become an inner light emitting part 50A and two outer light emitting parts 50B. In this example, the first protrusion P1 is a portion where the outer light emitting element 10B will be disposed and will become the outer wavelength conversion member 20B. Also, the second protrusion P2 is a portion where the inner light emitting element 10A will be disposed and will become the inner wavelength conversion member 20A. Furthermore, in this example, the plurality of first protrusions P1 are arranged to surround the second protrusion P2 in a plan view.

Subsequent to the process of forming grooves 300, as shown in FIG. 8, a process of placing light emitting elements 10 on the first principal face 121 of the light transmissive sheet 120 is performed. For example, light emitting elements 10 are disposed on the first principal face 121 of the light transmissive sheet 120. Then on the first principal face 121 an uncured bonding material 41 is supplied by using a dispenser. After supplying the bonding material 41, the bonding material 41 is hardened. The bonding material 41 is hardened by heating, for example. This bonds the light emitting elements 10 and the light transmissive sheet 120 via the bonding material 41. Element electrodes 12 are located on the faces of the light emitting elements 10 that oppose the faces in contact with the first principal faces 121.

Specifically, a light emitting element 10 is disposed on an upper surface of each of the first protrusion P1 and the second protrusion P2 with a light emitting surface of the light emitting element 10 facing the upper surface. In this example, in a plan view, an outer periphery of the light emitting element 10 disposed on the second protrusion P2 is positioned inside an outer periphery of the second protrusion P2. On the other hand, in a plan view, a part of an outer periphery of the light emitting element 10 disposed on the first protrusion P1 is positioned outside an outer periphery of the first protrusion P1. That is, in a plan view, a part of the upper surface (the lower surface in FIG. 8) of the light emitting element 10 disposed on the first protrusion P1 is positioned outside the first protrusion P1. As a result, in the subsequent step of disposing the light shielding member 31, the upper surface of the light emitting element 10 disposed on the second protrusion P2 is not covered by the light shielding member 31, and a part of the upper surface of the light emitting element 10 disposed on the first protrusion P1 is covered by the light shielding member 31.

In the process of disposing light emitting elements, as one example, the inner light emitting element 10A and the outer light emitting elements 10B are arranged using the same separation distance D1 in a plan view as described above. At this time, the outer light emitting elements 10B may be arranged such that on a line L that is an extension of the inner lateral face of an outer light emitting part 50B, the inner lateral face of an adjacent outer light emitting part 50B is positioned.

The process of disposing light emitting elements 10 is followed by disposing a light shielding member 31 containing an additive as shown in FIG. 9. In the process of disposing a light shielding member 31, a light shielding member 31 is formed, for example, by transfer molding using a mold, injection molding, compression molding, or the like. As another method, for example, a light shielding member 31 may be provided by preparing a resin material that softens when heated, burying light emitting elements 10 in the softened resin material, followed by hardening the resin material. The light shielding member 31 is disposed to fill the grooves 300 as well as covering the first principal face 121 and the lateral faces of the light transmissive sheet 120. In other words, the light shielding member 31 is partially disposed in the plurality of grooves 300 on the first principal face 121 of the light transmissive sheet 120, and collectively holds the plurality of light emitting elements 10.

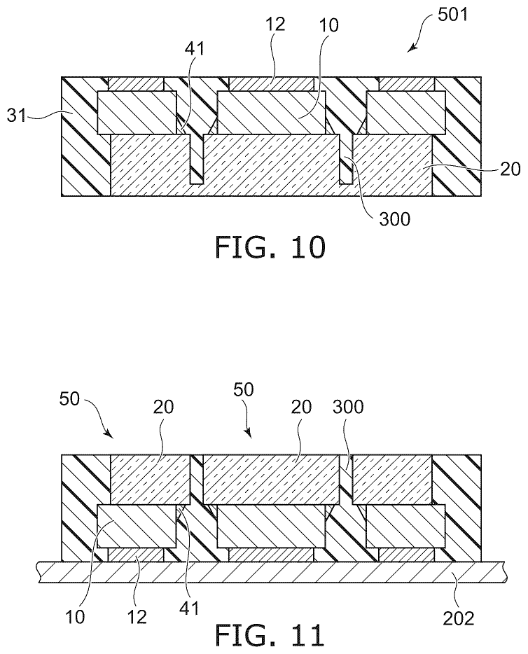

In the process of disposing a light shielding member 31, in the case in which the light shielding member 31 is disposed to cover the element electrodes 12 of the light emitting elements, the surfaces of the element electrodes 12 are exposed as shown in FIG. 10 by removing the light shielding member 31 by using a grinding machine, for example. At this time, the element electrodes 12 may be partly removed. Subsequently, a metal film is formed on the surfaces of the element electrodes 12 as needed. The metal film corresponds to the external electrodes. The metal film is formed by sputtering or vapor deposition, for example.

Subsequent to the step of disposing a light shielding member 31, the structure 501 that includes the light transmissive sheet 120, the light emitting elements 10, the element electrodes 12, the bonding material 42, and the light shielding member 31 is turned upside down and transferred from the first support member 201 to a second support member 202. Then a portion of the light transmissive sheet 120 is removed by using a grinding machine, for example. The light transmissive sheet 120 is further removed until the light shielding member 31 in the grooves 300 is exposed. Subsequently, the light shielding member 31 is cut in the regions on the outside of the light emitting parts 50 by using a blade or laser, for example, into individual light emitting devices. This divides the structure 501 described above into devices having multiple light emitting parts 50 as shown in FIG. 11. In the manner described above, a light emitting device 1 comprising an inner light emitting part 50A that includes an inner light emitting element 10A and an inner wavelength conversion member 20A disposed on the inner light emitting element 10A, and a plurality of outer light emitting parts 50B disposed around the inner light emitting part 50A, each including an outer light emitting element 10B and an outer wavelength conversion member 20B disposed on the outer light emitting element 10B, is manufactured.

### 5. Method of Manufacturing Light Emitting Device 3

A method of manufacturing a light emitting device 3 according to the third embodiment will be described with reference to FIG. 13 to FIG. 15. Firstly, a structure shown in FIG. 11 before being individualized for each light emitting device is prepared. The process of preparing the structure shown in FIG. 11 is the same as the method of manufacturing the light emitting device 1 according to the first embodiment.

Next, as shown in FIG. 13, a recess C is provided on the outer upper surface of the light shielding member 31 to surround the plurality of outer wavelength conversion members 20B. The recess C is provided, for example, by removing a part of the outer upper surface of the light shielding member 31 using a blade.

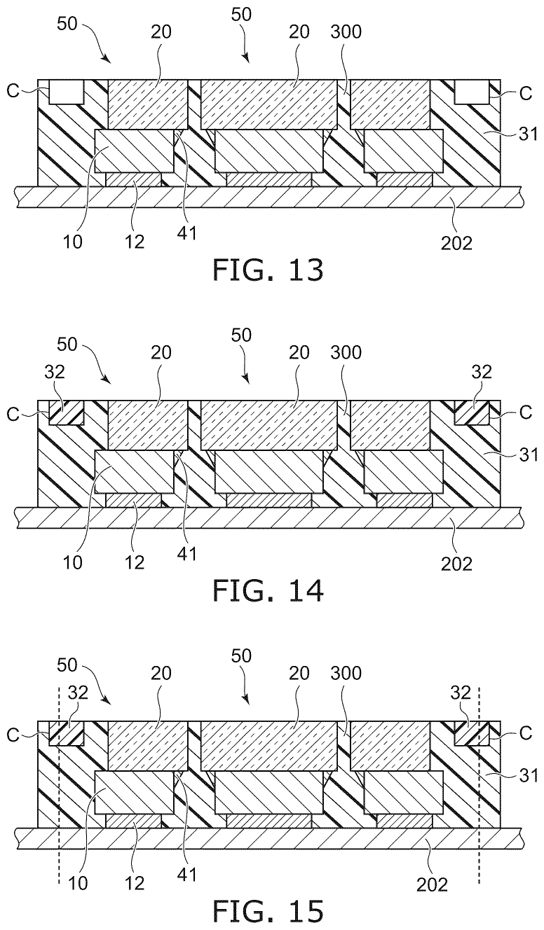

Next, as shown in FIG. 14, a light absorbing part 32 is disposed in the recess C provided on the outer upper surface of the light shielding member 31. The light absorbing part 32 is, for example, a resin member containing carbon black. The light absorbing part 32 is provided, for example, by using a transfer molding method, injection molding method, or compression molding method using a mold.

Next, as shown by the dotted line in FIG. 15, the light absorbing part 32 and the light shielding member 31 are cut using a blade or laser through the light absorbing part 32 to individualize the light emitting device 3. By cutting through the light absorbing part 32 and the light shielding member 31, an outer lateral face of the light absorbing part 32 and an outer lateral face of the light shielding member 31 are positioned on substantially the same plane on the outer lateral face of the light emitting device 3.

The light absorbing part 32 may also be provided, for example, by irradiating a region surrounding the plurality of outer wavelength conversion members 20B on the outer upper surface of the light shielding member 31 in the structure shown in FIG. 11 with laser light. In this example, the light shielding member 31 contains, for example, titanium oxide, and the titanium oxide located in the region irradiated with the laser light is altered to become the light absorbing part 32.

### 6. Other Embodiments

Certain embodiments of the present disclosure have been described above, but the invention is not limited to those described above. For example, in the light emitting device 1 according to one of the embodiments described above, the area of a first light emitting element 10B1 of a first light emitting part 50B1 disposed at a corner of the quadrangular region R is matched to the area of a second light emitting element 10B2 of a second light emitting part 50B disposed along a side of the quadrangular region R. The form is not limited to this, and the area of a second light emitting element 10B2 of a second light emitting part 50B disposed along a side of the quadrangular region R may be matched to the area of a first light emitting element 10B1 of a first light emitting part 50B1 disposed at a corner of the quadrangular region R.

Furthermore, the light emitting device 1 according to the first embodiment was adapted to bring the value and/or the density of the current flowing across a first light emitting element 10B1 of a first light emitting part 50B1 closer to the value and/or the density of the current flowing across a second light emitting element 10B2 of a second light emitting part 50B2 by adjusting the areas of the light emitting elements. As another way, it may be adapted to bring the value and/or the density of the current flowing across a first light emitting element 10B1 of a first light emitting part 50B1 closer to the value and/or the density of the current flowing across a second light emitting element 10B2 of a second light emitting part 50B2 by changing the resistance value of the wiring part of the substrate on which the outer light emitting parts 50B are mounted (e.g., by changing the ease of current flow by varying the size of the wiring parts of the substrate).

Alternatively, the value and/or the density of the current flowing across a first light emitting element 10B1 of a first light emitting part 50B1 may be brought closer to the value and/or the density of the current flowing across a second light emitting element 10B2 of a second light emitting part 50B2 by employing different types of bonding material such as solder for the first light emitting parts 50B1 and the second light emitting parts 50B2 in bonding the outer light emitting elements 10B and the substrate for mounting the outer light emitting parts 50B. Bringing the current density for the first light emitting elements 10B1 and the second light emitting elements 10B2 close together has the effect of reducing fluctuations in the forward voltage Vf of each light emitting element 10. Bringing the values of the current flowing across the first light emitting elements 10B1 and the second light emitting elements 10B2 close together has the effect of bringing the brightness of the light emitted by the light emitting elements 10 close together.

The present disclosure includes the forms described below.

In the foregoing, certain embodiments of the present invention have been described with reference to specific examples. The present disclosure, however, is not limited to these specific examples. All forms implementable by a person skilled in the art by suitably making design changes based on any of the embodiments of the present invention described above also fall within the scope of the present invention so long as they encompass the subject matter of the present invention. Furthermore, various modifications and alterations within the spirit of the present invention that could have been made by a person skilled in the art also fall within the scope of the present disclosure.

1. A light emitting device comprising:
an inner light emitting part comprising an inner light emitting element, and an inner wavelength conversion member disposed on the inner light emitting element, and
a plurality of outer light emitting parts disposed around the inner light emitting part and connected in parallel to one another, each outer light emitting part comprising an outer light emitting element, and an outer wavelength conversion member disposed on the outer light emitting element; wherein:
the outer light emitting parts include a first light emitting part that comprises a first light emitting element and a first wavelength conversion member, and a second light emitting part that comprises a second light emitting element and a second wavelength conversion member;
in a plan view, the area of the first wavelength conversion member is smaller than the area of the second wavelength conversion member; and
a ratio of the forward voltage of the first light emitting element to a forward voltage of the second light emitting element is in a range of 0.95 to 1.05.

2. The light emitting device according to claim 1, wherein the ratio of the area of the first light emitting element to the area of the second light emitting element in a plan view is 0.7 to 1.3.

3. The light emitting device according to claim 1 further comprising a light shielding member holding the inner light emitting part and the outer light emitting parts, wherein the light shielding member covers a portion of an upper face of the first light emitting element of the first light emitting part.

4. The light emitting device according to claim 3, wherein the light shielding member does not cover an upper face of the second light emitting element of the second light emitting part.

5. The light emitting device according to claim 3, wherein the light shielding member covers a portion of an upper face of the outer light emitting element in each of the outer light emitting parts.

6. The light emitting device according to claim 1, wherein, in a plan view, the inner light emitting part and the outer light emitting parts are arranged in a matrix in a quadrangular region, the first light emitting parts being disposed at the corners of the quadrangular region.

7. The light emitting device according to claim 3, wherein the light shielding member covers a portion of the upper face of the first light emitting element on a side that is not adjacent to another light emitting element among the outer light emitting parts in a plan view.

8. The light emitting device according to claim 1, wherein the inner light emitting element and the outer light emitting elements are arranged so as to have the same separation distance in a plan view.

9. The light emitting device according to claim 3, wherein a separation distance between an outer lateral face of the light shielding member and an outer lateral face of a first light emitting element is 0.3 times the length of a short side of the first light emitting element or larger.

10. The light emitting device according to claim 3 further comprising:
a light absorbing part that surrounds a plurality of the outer wavelength conversion members on an outer upper surface of the light shielding member, and that has a light absorption rate higher than that of the light shielding member.

11. The light emitting device according to claim 10, wherein the light shielding member has a recess on the outer upper surface that surrounds the plurality of the outer wavelength conversion members, the light absorbing part being disposed in the recess.

12. The light emitting device according to claim 10, wherein an outer lateral face of the light absorbing part is positioned on substantially the same plane as an outer lateral face of the light shielding member.

13. The light emitting device according to claim 1, wherein the light emitting device is operable by switching between a first irradiation mode in which only the inner light emitting part emits light and a second irradiation mode in which the inner light emitting part and the outer light emitting parts emit light.

14. A flashlight comprising:
a light source comprising the light emitting device according to claim 1.

15. A method for manufacturing a light emitting device, the method comprising:
preparing a light transmissive sheet having a first main surface and a second main surface on a side opposite the first main surface;
providing a plurality of protrusions including a first protrusion and a second protrusion on the light transmissive sheet in a plan view by providing a plurality of grooves on the first main surface;
disposing a plurality of light emitting elements on the plurality of protrusions, which comprises:
disposing the light emitting element on an upper surface of each of the first protrusion and the second protrusion with a light emitting surface of the light emitting element facing the upper surface,
disposing a light shielding member on the first main surface of the light transmissive sheet such that the light shielding member is disposed in the plurality of grooves and collectively holds the plurality light-emitting elements;
removing a part of the light transmissive sheet from the second main surface side to expose the light shielding member disposed in the grooves; and
obtaining, by individualizing, a light emitting device comprising an inner light emitting part that comprises:
an inner light emitting element and an inner wavelength conversion member disposed on the inner light emitting element and a plurality of outer light emitting parts disposed around the inner light emitting part, each outer light emitting part including an outer light emitting element and an outer wavelength conversion member disposed on the outer light emitting element; wherein:
the disposing the plurality of light emitting elements comprises:
a step of disposing the light emitting element on the second protrusion such that an outer periphery of the light emitting element disposed on the second protrusion is located inside an outer periphery of the second protrusion in a plan view, and
a step of disposing the light emitting element on the first protrusion such that a part of the outer periphery of the light emitting element disposed on the first protrusion is located outside an outer periphery of the first protrusion in a plan view;
the disposing of the light shielding member comprises:
not covering the upper surface of the light-emitting element disposed on the second protrusion with the light shielding member; and
covering a part of the upper surface of the light-emitting element disposed on the first protrusion with the light shielding member.

16. The method for manufacturing a light emitting device according to claim 15 further comprising providing a light absorbing part that surrounds a plurality of the outer wavelength conversion members on an outer upper surface of the light shielding member, and that has a light absorption rate higher than that of the light shielding member, after the removing the part of the light transmissive sheet.

17. The method for manufacturing a light emitting device according to claim 16, wherein: the providing the light absorbing part comprises:
providing a recess on the outer upper surface of the light shielding member that surrounds the plurality of the outer wavelength conversion members, and
a step of disposing the light absorbing part in the recess.

18. The method for manufacturing a light emitting device according to claim 16, wherein the obtaining the of light emitting device comprises individualizing by cutting through the light absorbing part and the light shielding member in a plan view.
